(19) United States
(12) Patent Application Publication
(10) Pub. No.: US 2014/0299170 A1
(43) Pub. Date: Oct. 9, 2014

(54) THERMOELECTRIC DEVICE, ESPECIALLY INTENDED TO GENERATE AN ELECTRIC CURRENT IN AN AUTOMOTIVE VEHICLE, AND PROCESS FOR MANUFACTURING SAID DEVICE

(71) Applicant: VALEO SYDSTEMS THERMIQUES, Les Mesnil Saint Denis (FR)

(72) Inventors: Michel Simonin, Voisins Le Bretonneux (FR); Patrick Boisselle, Laval (FR); Cédric De Vaulx, Autouillet (FR)

(21) Appl. No.: 14/353,423

(22) PCT Filed: Nov. 22, 2012
(86) PCT No.: PCT/EP2012/073404

§ 371 Date: Apr. 22, 2014

(30) Foreign Application Priority Data
Nov. 23, 2011 (FR) 1160689

(51) Int. Cl. H01L 35/32; H01L 35/34

(52) U.S. Cl. CPC H01L 35/325; H01L 35/34
USPC 136/208; 136/201; 228/179.1

(57) ABSTRACT

The invention relates to a thermoelectric device comprising: a plurality of elements (4), called thermoelectric elements, allowing an electrical current to be produced from a temperature gradient between two of their faces (3a, 3b), called contact faces; electrically conductive tracks (20); and a solder joint between said contact faces (3a, 3b) and the electrically conductive tracks. According to the invention, said solder comprises an alloy based on aluminum and silicon. The invention also relates to a process for manufacturing such a device, using solid-state soldering.

The present invention relates to a thermoelectric device, particularly designed to generate an electric current in an automotive vehicle, and to a method for manufacturing said device.

Thermoelectric devices have already been proposed using elements, referred to as thermoelectric elements, for generating an electric current in the presence of a temperature gradient between two of their opposing faces according to the phenomenon known as the Seebeck effect. These devices comprise a stack of first tubes, which are designed to circulate the exhaust gases of an engine, and second tubes, which are designed to circulate a coolant of a cooling circuit. The thermoelectric elements are sandwiched between the tubes so as to experience a temperature gradient originating from the difference in temperature between the exhaust gases, which are hot, and the coolant, which is cold.

Such devices are particularly advantageous as they allow electricity to be produced based on the conversion of the heat originating from the exhaust gases of the engine. They therefore offer the possibility of reducing the fuel consumption of the vehicle by replacing, at least partially, the alternator that is commonly provided therein to generate electricity from a belt driven by the crankshaft of the engine.

A disadvantage of the thermoelectric devices that are currently used is their high manufacturing cost, particularly due to the rare materials used to produce the thermoelectric elements, and a first object of the invention is to allow the use of lower-cost thermoelectric elements compatible with the manufacturing costs encountered in the automobile industry. Therefore, the invention proposes the use of thermoelectric elements produced from materials of economic interest by virtue of the use of constituent parts that are available in large quantities.

This being the case, in order to have a sufficiently high level of current and voltage, it is necessary for the thermoelectric elements to be connected together, in series and/or in parallel, using electrically conductive tracks provided on the surface of the tubes. Different solutions have already been studied for ensuring the soldering of the thermoelectric elements on the conductive tracks. With regard to thermoelectric elements using relatively common materials, soldering with silver has already been attempted successfully.

However, such a material is expensive. Furthermore, in order to avoid the phenomena of metal diffusion between the thermoelectric elements and the solder, layers of anti-diffusion materials need to be provided on the surface of the thermoelectric elements, such as nickel layers that are a few micrometres thick.

The use of silver for the solder and the need to protect the thermoelectric elements in order to prevent the diffusion phenomena therefore work against the intended aim.

The intention of the present invention is to improve the situation and to this end it proposes a thermoelectric device comprising a plurality of elements, referred to as thermoelectric elements, allowing an electric current to be created from a temperature gradient applied between two of the faces of said elements, referred to as contact faces, electrically conductive tracks and a solder joint between said contact faces and said electrically conductive tracks. According to the invention, said solder comprises an aluminium- and silicon-based alloy.

In this way, a solder is provided that can originate from solid phase soldering, which limits the risks of metal diffusion from the thermoelectric elements. Solid phase soldering is understood to be soldering in which the material used for soldering is supplied in a paste form, below its liquidus.

It is thus possible to avoid the use of anti-diffusion cladding. The selection of such an alloy, using components that are less expensive than silver, also contributes to the reduction of costs.

According to various embodiments, which can be taken in combination or separately:
the aluminium content of the solder by weight is preponderant;
the silicon content of the solder by weight is less than 20%;
the silicon content of the solder by weight is between 5% and 15%;
the conductive tracks are made of nickel and/or copper;
the thermoelectric elements are silicon-alloy based;
the thermoelectric elements are of the Mg2Si or MnSi type.

The invention further relates to a method for manufacturing a thermoelectric device comprising a plurality of elements, referred to as thermoelectric elements, allowing an electric current to be created from a temperature gradient applied between two of the faces of said elements, referred to as contact faces, and electrically conductive tracks. According to said method, a solder joint is produced between said contact faces and said electrically conductive tracks by solid phase soldering.

As has been previously stated, the risks of diffusion are thus limited without having to use specific cladding layers.

According to various embodiments, which can be taken in combination or separately:
said soldering is carried out by applying pressure to the elements to be soldered;
said soldering is carried out under an inert atmosphere;
said soldering is carried out in a vacuum;
said solder joint is produced using a solder material with a melting point above 580° C.;
the soldering material comprises an aluminium- and silicon-based alloy;
the soldering material is made from a strip, the thickness of which is between 20 and 500 micrometres, and in particular is between 50 and 200 micrometres;
the soldering material originates from a strip capable of simultaneously forming the conductive tracks and said solder joint;
said strip comprises an aluminium core cladded on at least one of its faces with an aluminium and silicon-based alloy.

The invention will be better understood upon reading the following description, which is provided by way of illustration and non-limiting example only, and with reference to the appended drawings, in which:

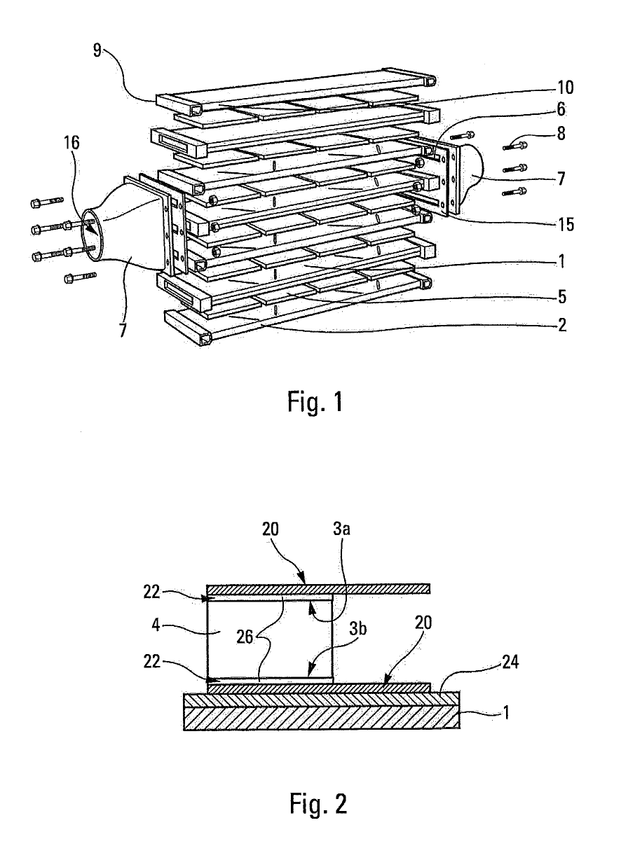

FIG. 1 is a perspective, exploded view of an example of a thermoelectric device;

FIG. 2 is a schematic, longitudinal section of a tube of the device of FIG. 1, shown in part, and a thermoelectric element disposed on said tube, before soldering, according to a first embodiment of the invention;

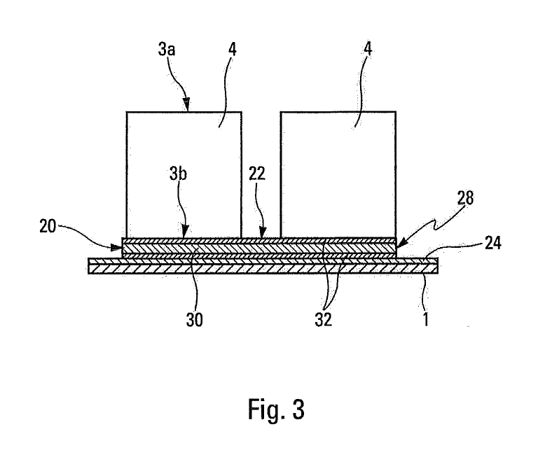

FIG. 3 is a schematic, longitudinal section of a tube of the device of FIG. 1 and a pair of thermoelectric elements disposed on said tube, before soldering, according to a second embodiment of the invention.

FIG. 1 shows a thermoelectric device comprising thermally conductive supports in contact with a hot or cold source, such as a plurality of tubes 1 for circulating a first fluid alternating with a plurality of tubes 2 for circulating a second fluid. In this case, said tubes 1, 2 extend parallel to each other in the same direction.

The tubes 1 for circulating the first fluid are configured, for example, for circulating a fluid, referred to as hot fluid. This can involve exhaust gases of a combustion engine of an automotive vehicle. The tubes 2 for circulating the second fluid are configured, for example, for circulating a fluid, referred to as cold fluid, the temperature of which is below the temperature of the first fluid. This can involve a coolant, such as a mixture of water and glycol, originating, for example, from a low-temperature cooling loop of the vehicle.

In this case, there are three tubes 1 for circulating exhaust gases and there are four tubes 2 for circulating the coolant.

Said device further comprises a plurality of elements, referred to as thermoelectric elements, allowing an electric current to be created from a temperature gradient applied between two of the faces of said elements, referred to as contact faces.

According to a first aspect of the invention, said thermoelectric elements are based on materials that are relatively common and are therefore not very expensive. This involves, for example, silicon-alloy based materials. It is thus possible for thermoelectric elements of the Mg2Si or MnSi type to be used. According to the Seebeck effect, such elements allow an electric current to be created in a load connected to said contact faces.

Said thermoelectric elements 4, which can be schematically seen in FIGS. 2 and 3, are shown here in a substantially parallelepiped shape and the contact faces 3a, 3b are opposite each other. Said contact faces are disposed facing the external surface of said tubes 1, 2 for circulating the first and second fluid. It is noteworthy that in FIGS. 2 and 3, for the sake of simplicity, the cold tube is not shown and the hot tube 1 is only shown in part, with only its external wall located facing the thermoelectric elements 4 being shown.

The thermoelectric elements 4 can be, for a first part, elements of a first type, referred to as P, allowing a difference in electric potential to be established in one direction, referred to as a positive direction, when they experience a given temperature gradient and, for the other part, elements of a second type, referred to as N, allowing a difference in electric potential to be created in an opposite direction, referred to as a negative direction, when they experience the same temperature gradient.

With further reference to FIG. 1, it can be seen that the thermoelectric elements 4 in this case are distributed in layers 5 provided between the tubes 1 for circulating the first fluid and the tubes 2 for circulating the second fluid.

The thermoelectric elements are electrically connected. In particular, the thermoelectric elements of type P and the thermoelectric elements of type N of the same layer 5 can be connected so as to allow the circulation of the current in series from an element of the first type to an element of the second type. The thermoelectric elements that are thus connected form a basic conductive cell and the cells that are obtained can be connected in series and/or in parallel. Inside the same conductive cell, thermoelectric elements of the same type can be connected in parallel in order to increase the intensity of the supplied current.

The layers 5 are electrically connected together, in series and/or in parallel. An electrical connector, not shown, allows the device to be connected to an external electrical circuit. The current generated by all of said thermoelectric elements is thus transmitted to the electrical circuit to which said device is connected.

Said circulation tubes 1, 2 have, for example, a flat section along a direction of elongation, orthogonal to the direction of extension of the tubes. Said circulation tubes 1, 2 thus can be flat tubes. It is therefore understood that they have two large, flat, parallel faces connected by small sides. The thermoelectric elements 4 are in contact with one and/or the other of the flat faces of the tubes 1, 2 via their contact faces 3a, 3b.

Said tubes 1, 2 have, for example, multiple channels. Said tubes 2 designed for circulating the cold fluid are made, for example, of aluminium and/or aluminium alloy. In particular, they are extruded. Their channels can have a round section. The tubes 1 designed for circulating the hot fluid are made in particular from stainless steel. They are shaped for example by profiling, welding and/or soldering. Their channels for the passage of the fluid are separated, in particular by partitions linking the opposite flat faces of the tubes.

Said device further comprises, for example, a collector plate 15 on each of the ends of said tubes 1 for circulating the first fluid. Said collector plate 15 is provided with holes 6, into which the ends of said tubes 1 for circulating the first fluid are inserted.

Said device can also comprise headers 7 in fluid communication with the ends of said tubes 1 for circulating the first fluid and fixed to the collector plates 5 by means of screws 8. Said headers comprise a hole 16 for the entry and/or the exit of the first fluid.

Each of the ends of said tubes 2 for circulating the second fluid can be provided with collectors 9 allowing said tubes 2 for circulating the second fluid to be placed in communication with a header, not shown, of the second fluid by means of holes 10 opening out on a lateral face of the bundle defined by the stack of tubes 1, 2 for circulating the first and second fluid.

Said thermoelectric device further comprises electrically conductive tracks and a solder joint between said contact faces and the electrically conductive tracks.

In FIGS. 2 and 3, reference numerals 20 and 22 are used for said electrically conductive tracks and the material used to form said solder, respectively. They are shown herein in their form before soldering. After soldering, the material used for soldering is distributed between the thermoelectric elements 4 and the electrically conductive tracks 20 so as to form said solder joint, which establishes an electrically and thermally conductive bond between said thermoelectric elements 4 and said tracks 20.

Said electrically conductive tracks 20 are provided so as to be in contact with the hot and/or cold thermally conductive supports, i.e. the hot 1 and/or cold 2 tubes in this case. The conductive tracks are, for example, made of nickel and/or copper. A layer 24 of thermally conductive and electrically isolating material can be provided between the hot and/or cold thermally conductive supports and said conductive tracks 20, such as a layer of aluminium.

In other words, in said device, the exhaust gases pass through the hot tubes, whereas the coolant passes through the cold tubes. A temperature gradient is thus established between the hot tubes and the cold tubes. It is applied to the thermoelectric elements 4 through the aluminium layer 24, the conductive tracks 20 and the solder joint. It allows said thermoelectric elements 4 to generate an electric current conducted by the solder and the conductive tracks.

According to the invention, said solder comprises an aluminium- and silicon-based alloy. Therefore, a solder is used of which the materials are relatively common and thus have a low manufacturing cost. Furthermore, a solution is provided that limits the metal diffusion from the thermoelectric elements 4 without having to use a layer of anti-diffusion material. In effect, such a solder can originate from solid phase soldering. After soldering, the bond has excellent thermal, electrical and mechanical characteristics.

Such a solder is also able to withstand operating temperatures of the order of 500° C., and even 530° C., i.e. temperatures compatible with the circulation of exhaust gases in the tubes 1, at a temperature of the order of 750° C. In this way, a solution is provided that is particularly suitable for applications in the automotive field.

In this respect, said alloy will be used in particular on the hot source side, i.e. the hot tubes 1 in this case.

The aluminium content of the solder by weight is preferably preponderant. The silicon content of the solder by weight is therefore lower, for example less than 20%. In particular, it can be between 5% and 15%. More particularly, it is approximately 10%.

The invention further relates to a method for manufacturing a thermoelectric device as described above. According to said method, the solder joint between said contact faces 3a, 3b of the thermoelectric elements 4 and said electrically conductive tracks 20 is produced by solid phase soldering. As has already been stated, in this way metal diffusion is avoided without having to use an anti-diffusion layer between said thermoelectric elements 4 and said electrically conductive tracks 20.

According to one aspect of the invention, said soldering can be carried out by applying pressure to the elements to be soldered. In the aforementioned configuration, this can involve means outside of the device exerting a force on the stack of tubes 1, 2 orthogonal to their large flat faces.

According to a further aspect of the invention, soldering conditions can be employed that allow oxidation of the soldering material to be avoided. This can involve, for example, soldering under an inert atmosphere. According to a variant, said soldering can be carried out in a vacuum.

Said solder joint can be produced for example using a soldering material 22 with a melting point, under normal pressure conditions, that is higher than 580° C. This involves a melting point that is particularly between 580° C. and 600° C. For its part, the soldering temperature is maintained below 580° C., for example, and below 570° C. in particular. In this way it is possible to have soldering without reaching the liquidus, whilst saving the thermoelectric elements 4 during soldering and having a solder joint that can withstand the operating conditions. In particular, a soldering material 22 can be selected that comprises an aluminium-and silicon-based alloy, as previously described. In such an alloy, the quantity of silicon used allows the temperature of the melting point to be controlled.

According to a first embodiment, shown in FIG. 2, the soldering material 22 is made from a strip 26, the thickness of which is between 20 and 500 micrometres, and is in particular between 50 and 200 micrometres. It is disposed between the conductive tracks 20 and the thermoelectric elements 4. In this case it corresponds with the contact surfaces 3a, 3b of said thermoelectric elements 4.

According to a further embodiment, shown in FIG. 3, the soldering material 22 originates from a strip 28 capable of simultaneously forming the conductive tracks and said solder joint. Therefore, it is no longer necessary for separate conductive tracks to be provided.

Said strip 28 comprises, for example, an aluminium core 30 cladded on at least one of its faces, in this case both faces, with an aluminium- and silicon-based alloy 32.

After soldering, said core 30 defines the conductive tracks, whereas the cladding alloy defines the solder, on one side, between the conductive tracks and the thermoelectric elements 4 and, on the other side, between the electrically conductive support, in this case the tubes 1, 2, and the conductive tracks.

The thickness of the strip is configured depending on the current to be carried. Typically, it can be between 0.5 and 2 mm. Furthermore, the thickness of said cladding alloy can represent between 10% and 30% of the total thickness of the strip 28.

Clearly, the device described above, with reference to FIG. 1, is only an example of a thermoelectric device according to the invention that can be applied to devices with numerous other configurations. In particular, the thermally conductive supports provided with said electrically conductive tracks and said solder can be tubes of other shapes, made of other materials or arranged differently. It can even involve thermally conductive fins connected to the cold source and/or to the hot source, particularly by means of fluid circulation tubes.

1. Thermoelectric device comprising a plurality of elements (4), referred to as thermoelectric elements, allowing an electric current to be created from a temperature gradient applied between two of the faces (3a, 3b) of said elements, referred to as contact faces, electrically conductive tracks (20) and a solder joint between said contact faces (3a, 3b) and said electrically conductive tracks, wherein said solder comprises an aluminum and silicon-based alloy.

2. Device according to claim 1, wherein the aluminum content of the solder by weight is preponderant.

3. Device according to claim 1, wherein the silicon content of the solder by weight is less than 20%.

4. Device according to claim 1, wherein the silicon content of the solder by weight is between 5% and 15%, and is 10% in particular.

5. Device according to claim 1, wherein said thermoelectric elements (4) are silicon-alloy based.

6. Device according to claim 5, wherein said thermoelectric elements (4) are of the Mg₂Si or MnSi type.

7. Method for manufacturing a thermoelectric device comprising a plurality of elements (4), referred to as thermoelectric elements, allowing an electric current to be created from a temperature gradient applied between two of the faces (3a, 3b) of said elements, referred to as contact faces, and electrically conductive tracks (20), according to which method a solder joint is produced between said contact faces (3a, 3b) and said electrically conductive tracks (20) by solid phase soldering.

8. Method according to claim 7, wherein said soldering is carried out by applying pressure to the elements to be soldered.

9. Method according to claim 7, wherein said soldering is carried out under an inert atmosphere.

10. Method according to claim 7, wherein said soldering is carried out in a vacuum.

11. Method according to claim 7, wherein said solder joint is produced using a soldering material (22) with a melting point above 580° C.

12. Method according to claim 11, wherein said soldering material (22) comprises an aluminum and silicon-based alloy.

13. Method according to claim 11, wherein said soldering material (22) is formed by a strip (26), the thickness of which is between 20 and 500 micrometres, and in particular between 50 and 200 micrometres.

14. Method according to claim 11, wherein said soldering material (22) originates from a strip (28) capable of simultaneously forming the conductive tracks and said solder joint.

15. Method according to claim 14, wherein said strip (28) comprises an aluminum core (30) cladded on at least one of its faces with an aluminum and silicon-based alloy (32).
